(19) United States
(12) Patent Application Publication
(10) Pub. No.: US 2025/0287623 A1
(43) Pub. Date: Sep. 11, 2025

(54) RECTIFYING DEVICE

(71) Applicant: Japan Display Inc., Tokyo (JP)

(72) Inventors: Masumi NISHIMURA, Tokyo (JP); Ryo ONODERA, Tokyo (JP)

(73) Assignee: Japan Display Inc., Tokyo (JP)

(21) Appl. No.: 19/220,580

(22) Filed: May 28, 2025

Related U.S. Application Data
(63) Continuation of application No. PCT/JP2023/041068, filed on Nov. 15, 2023.

(30) Foreign Application Priority Data
Nov. 29, 2022 (JP) 2022-189983

(51) Int. Cl. H10D 8/60; H10D 8/01; H10D 62/40; H10D 62/85

(52) U.S. Cl. CPC H10D 8/60; H10D 8/051; H10D 62/405; H10D 62/8503

(57) ABSTRACT

A rectifying device includes an amorphous substrate, an orientation control layer on the amorphous substrate, a first gallium nitride-based semiconductor layer and a second gallium nitride-based semiconductor layer on the orientation control layer, a first electrode forming a Schottky junction with the first gallium nitride-based semiconductor layer, and a second electrode forming an ohmic junction with the second gallium nitride-based semiconductor layer.

### CROSS-REFERENCE TO RELATED APPLICATIONS

This application is a Continuation of International Patent Application No. PCT/JP2023/041068, filed on Nov. 15, 2023, which claims the benefit of priority to Japanese Patent Application No. 2022-189983, filed on Nov. 29, 2022, the entire contents of which are incorporated herein by reference.

### FIELD

An embodiment of the present invention relates to structure of a rectifying device having a Schottky junction and formed of a gallium nitride-based semiconductor.

### BACKGROUND

Schottky barrier diodes using gallium nitride-based compound semiconductors are known. For example, a Schottky barrier diode is disclosed in which a buffer layer having an aluminum nitride layer and a gallium nitride layer alternately laminated on a silicon substrate and a gallium nitride layer forming a Schottky junction are disposed on the buffer layer (refer to Japanese laid-open patent publication No. 2023-060212).

In conventional gallium nitride-based compound semiconductor devices, expensive substrates such as single-crystal silicon substrates, single-crystal gallium nitride substrates, or sapphire substrates are used, and high-temperature processes are required for crystal growth. Therefore, high cost is a problem. It is considered that the cost can be reduced if the gallium nitride-based semiconductor device can be manufactured at a process temperature of 600° C. or lower by using a glass substrate of a large area such as that used for manufacturing liquid crystal display panels.

### SUMMARY

A rectifying device in an embodiment according to the present invention includes an amorphous substrate, an orientation control layer on the amorphous substrate, a first gallium nitride-based semiconductor layer and a second gallium nitride-based semiconductor layer on the orientation control layer, a first electrode forming a Schottky junction with the first gallium nitride-based semiconductor layer, and a second electrode forming an ohmic junction with the second gallium nitride-based semiconductor layer.

### BRIEF DESCRIPTION OF DRAWINGS

FIG. 1A is a plan view of a rectifying device using a gallium nitride-based semiconductor layer according to an embodiment of the present invention.

FIG. 1B is a cross-sectional view of a rectifying device using a gallium nitride-based semiconductor layer according to an embodiment of the present invention.

FIG. 2A is a diagram illustrating a step of forming an orientation control layer in the manufacturing process of a rectifying device using a gallium nitride-based semiconductor layer according to an embodiment of the present invention.

FIG. 2B is a diagram illustrating a step of preparing a second gallium nitride-based semiconductor layer in a manufacturing process of a rectifying device using a gallium nitride-based semiconductor layer according to an embodiment of the present invention.

FIG. 2C is a diagram illustrating a step of forming a first gallium nitride-based semiconductor layer in a manufacturing process of a rectifying device using a gallium nitride-based semiconductor layer according to an embodiment of the present invention.

FIG. 2D is a diagram illustrating a step of exposing the upper surface of the second gallium nitride-based semiconductor layer from the first gallium nitride-based semiconductor layer in the manufacturing process of a rectifying device using the gallium nitride-based semiconductor layer according to an embodiment of the present invention.

FIG. 3A is a cross-sectional view of a rectifying device using a gallium nitride-based semiconductor layer according to an embodiment of the present invention.

FIG. 3B is a cross-sectional view of a rectifying device using a gallium nitride-based semiconductor layer according to an embodiment of the present invention.

FIG. 3C is a cross-sectional view of a rectifying device using a gallium nitride-based semiconductor layer according to an embodiment of the present invention.

FIG. 4A is a plan view of a rectifying device using a gallium nitride-based semiconductor layer according to an embodiment of the present invention.

FIG. 4B is a cross-sectional view of a rectifying device using a gallium nitride-based semiconductor layer according to an embodiment of the present invention.

FIG. 5A is a cross-sectional view of a rectifying device using a gallium nitride-based semiconductor layer according to an embodiment of the present invention.

FIG. 5B is a cross-sectional view of a rectifying device using a gallium nitride-based semiconductor layer according to an embodiment of the present invention.

### DESCRIPTION OF EMBODIMENTS

Hereinafter, embodiments of the present invention are described with reference to the drawings. However, the present invention can be implemented in many different aspects, and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by a, b, etc.) and a detailed description may be omitted as appropriate. The terms “first” and “second” appended to each element are convenient terms used to distinguish them and have no further meaning except as otherwise explained.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

### First Embodiment

A rectifying device according to an embodiment of the present invention will be described in detail. The rectifying device according to an embodiment of the present invention is made of a gallium nitride-based semiconductor and includes a Schottky junction.

### 1. Structure of Rectifying Device

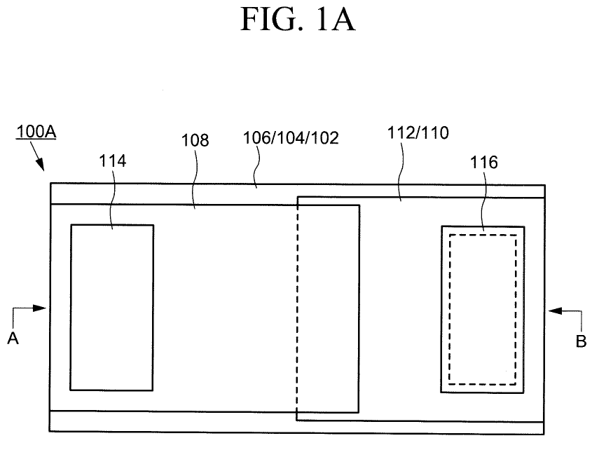

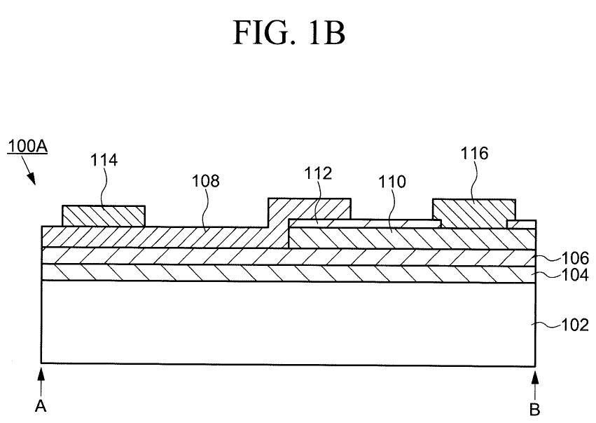

FIG. 1A and FIG. 1B show a structure of the rectifying device 100A according to the present embodiment. FIG. 1A shows a plan view of the rectifying device 100A. FIG. 1B shows a cross-sectional view corresponding to the section A-B shown in FIG. 1A. As shown in FIG. 1A and FIG. 1B, the rectifying device 100A includes an orientation control layer 106, a first gallium nitride-based semiconductor layer 108, a second gallium nitride-based semiconductor layer 110, a first electrode 114, and a second electrode 116 disposed on an amorphous substrate 102.

The orientation control layer 106 is disposed to cover the upper surface of the amorphous substrate 102. The first gallium nitride-based semiconductor layer 108 and the second gallium nitride-based semiconductor layer 110 are disposed side by side on the amorphous substrate 102 and are arranged to be in contact with the orientation control layer 106. That is, the rectifying device 100A of the present embodiment includes a structure in which the first gallium nitride-based semiconductor layer 108 and the second gallium nitride-based semiconductor layer 110 are not laminated in the vertical direction, but are arranged on the orientation control layer 106 in parallel with each other.

An insulating layer 112 may be disposed on the upper surface of the second gallium nitride-based semiconductor layer 110. When the insulating layer 112 is disposed, the first gallium nitride-based semiconductor layer 108 is disposed to overlap the second gallium nitride-based semiconductor layer 110 from the upper surface of the insulating layer 112 over the stepped portion of the second gallium nitride-based semiconductor layer 110. It is possible to prevent the first gallium nitride-based semiconductor layer 108 from coming into direct contact with the upper surface of the second gallium nitride-based semiconductor layer 110, by arranging the insulating layer 112. With such a structure, as will be described later, the first gallium nitride-based semiconductor layer 108 can be selectively etched in the manufacturing process without affecting the second gallium nitride-based semiconductor layer 110. The insulating layer 112 may be optional and may be excluded.

As shown in FIG. 1B, the end (side surface exposed from the insulating layer 112) of the second gallium nitride-based semiconductor layer 110 is disposed in contact with the first gallium nitride-based semiconductor layer 108. The first gallium nitride-based semiconductor layer 108 is in contact with the end of the second gallium nitride-based semiconductor layer 110 to form a semiconductor junction. The rectifying device 100A includes at least two semiconductor layers, a first gallium nitride-based semiconductor layer 108 and a second gallium nitride-based semiconductor layer 110, and the two semiconductor layers have the same conductivity type. That is, the first gallium nitride-based semiconductor layer 108 and the second gallium nitride-based semiconductor layer 110 have an n-type or p-type conductivity type.

The first gallium nitride-based semiconductor layer 108 and the second gallium nitride-based semiconductor layer 110 have the same conductivity type, although the dopant concentration is different. In other words, the first gallium nitride-based semiconductor layer 108 and the second gallium nitride-based semiconductor layer 110 have different carrier concentrations and accordingly different electrical conductivities. Specifically, the dopant concentration of the first gallium nitride-based semiconductor layer 108 is relatively lower than that of the second gallium nitride-based semiconductor layer 110, and the electrical conductivity is also lowered. It is preferable that the dopant concentration (or carrier concentration) of the first gallium nitride-based semiconductor layer 108 and the dopant concentration (or carrier concentration) of the second gallium nitride-based semiconductor layer 110 have a concentration difference of 10 times or more. Specifically, the dopant concentration (or carrier concentration) of the first gallium nitride-based semiconductor layer 108 is preferably about 5×10¹⁵ to 1×10¹⁷/cm³, and the dopant concentration (or carrier concentration) of the second gallium nitride-based semiconductor layer 110 is preferably about 5×10¹⁸ to 5×10²¹/cm³. It is possible to form a satisfactory Schottky barrier with the first electrode 114 by lowering the dopant concentration (or carrier concentration) of the first gallium nitride-based semiconductor layer 108, and it is possible to form good ohmic contact with the second electrode 116 by increasing the dopant concentration (or carrier concentration) of the second gallium nitride-based semiconductor layer 110.

The first electrode 114 is disposed to contact the upper surface of the first gallium nitride-based semiconductor layer 108. The first electrode 114 is formed of a material capable of forming a Schottky junction with the first gallium nitride-based semiconductor layer 108. That is, the first electrode 114 is formed of a metal having a work function larger than that of the first gallium nitride-based semiconductor layer 108.

The second electrode 116 is disposed to contact the upper surface of the second gallium nitride-based semiconductor layer 110. The second electrode 116 is disposed in ohmic contact with the second gallium nitride-based semiconductor layer 110. In order to make ohmic contact with the second gallium nitride-based semiconductor layer 110, the second electrode 116 is preferably formed of a metal having a work function smaller than that of the second gallium nitride-based semiconductor layer 110. Further, the second electrode 116 may be formed of the same metal as the metal for forming the first electrode 114. Since the dopant concentration of the second gallium nitride-based semiconductor layer 110 is high, ohmic contact can be formed even if the second electrode 116 is formed of the same metal as the first electrode 114.

As shown in FIG. 1B, an underlying insulating layer 104 may be disposed between the amorphous substrate 102 and the orientation control layer 106. It is possible to enhance the adhesion of the orientation control layer 106 and to prevent the diffusion of impurities from the amorphous substrate 102 to the first gallium nitride-based semiconductor layer 108 and the second gallium nitride-based semiconductor layer 110, by providing the underlying insulating layer 104.

The rectifying device 100A according to the present embodiment includes the above-described structure. Details of each layer constituting the rectifying device 100A will be described below.

### 1-1. Amorphous Substrate

The amorphous substrate 102 is a non-crystalline substrate. In other words, the amorphous substrate 102 is a substrate formed of an amorphous material. The amorphous substrate 102 preferably has an expansion coefficient smaller than 50×10⁻⁷/° C. and a strain point of 600° C. or higher. A glass substrate can be exemplified as the amorphous substrate 102. The glass substrate as the amorphous substrate 102 is preferably an alkali metal such as sodium (Na) with a content of 0.1% or less. Such glass substrates are, for example, glass substrates formed of aluminoborosilicate glass or aluminosilicate glass. Such glass substrates are used in liquid crystal displays and organic electroluminescence (OLED) displays, and large-area glass substrates called mother glass are available in the market. It is possible to prepare a gallium nitride semiconductor device using a large-area glass substrate by applying a glass substrate as the amorphous substrate 102.

The amorphous substrate 102 preferably has a heat resistance of about 600° C. It is not necessary to have a heat resistance of 1000° C. or higher like a sapphire substrate. The first gallium nitride-based semiconductor layer 108 and the second gallium nitride-based semiconductor layer 110 are formed by sputtering. The metal organic chemical vapor deposition (MOCVD) method can form a single crystal gallium nitride-based semiconductor film, but a substrate temperature of 1000° C. or higher is required for the film growth. On the other hand, in the present embodiment, a sputtering method is used, and the first gallium nitride-based semiconductor layer 108 and the second gallium nitride-based semiconductor layer 110 having crystallinity are formed on the orientation control layer 106 at a substrate temperature of 600° C. or less. The first gallium nitride-based semiconductor layer 108 and the second gallium nitride-based semiconductor layer 110 used in the rectifying device 100A of the present embodiment are capable of lowering the film deposition temperature, and a flexible resin substrate such as a polyimide substrate, an acrylic substrate, a siloxane substrate, and a fluor resin substrate can be used as the amorphous substrate 102 in addition to a glass substrate.

### 1-2. Underlying Insulating Layer

As shown in FIG. 1B, the underlying insulating layer 104 may be disposed on the amorphous substrate 102 as an additional configuration. The underlying insulating layer 104 is formed of a single layer structure of an inorganic insulating film or a stacked structure of a plurality of inorganic insulating films. As the inorganic insulating film forming the underlying insulating layer 104, a silicon nitride film, a silicon oxide film, a silicon oxynitride film, an aluminum nitride film, an aluminum oxide film, an aluminum oxynitride film, and the like can be exemplified. Although FIG. 1B shows a single layer structure of the underlying insulating layer 104, it may have a structure where at least two layers of inorganic insulating layers are laminated. For example, the underlying insulating layer 104 may have a structure in which a silicon nitride film and a silicon oxide film are laminated in order from the amorphous substrate 102 side. The silicon nitride film of the underlying insulating layer 104 preferably has a film thickness of, for example, 20 nm to 500 nm, and the silicon oxide film of the underlying insulating layer 104 preferably has a film thickness of, for example, 20 nm to 500 nm.

In order to form the first gallium nitride-based semiconductor layer 108 and the second gallium nitride-based semiconductor layer 110 having excellent crystallinity and low defect density, it is preferable to reduce the impurity concentration. When a glass substrate is used as the amorphous substrate 102, since the glass substrate contains a small amount of alkali metal (such as sodium), contamination of the first gallium nitride-based semiconductor layer 108 and the second gallium nitride-based semiconductor layer 110 by the alkali metal is a concern. Therefore, it is possible to prevent diffusion of the alkali metal and to prevent contamination of impurities by providing the underlying insulating layer 104 on the lower layer side of the first gallium nitride-based semiconductor layer 108 and the second gallium nitride-based semiconductor layer 110. For example, since the silicon nitride film used as the underlying insulating layer 104 has a thickness of 20 nm or more, diffusion of an alkali metal from the amorphous substrate 102 to the first gallium nitride-based semiconductor layer 108 and the second gallium nitride-based semiconductor layer 110 can be prevented.

The underlying insulating layer 104 has a function of improving the adhesion of the orientation control layer 106 disposed thereon. For example, peeling of the orientation control layer 106 can be prevented by using a silicon oxide film having a film thickness of 20 nm or more as the underlying insulating layer 104.

As described above, it is possible to form the first gallium nitride-based semiconductor layer 108 and the second gallium nitride-based semiconductor layer 110 having excellent crystallinity and low defect density on the amorphous substrate 102 by providing the underlying insulating layer 104 with both a function as a barrier layer against impurities and a function as an adhesion improving layer with respect to the orientation control layer 106.

### 1-3. Orientation Control Layer

The orientation control layer 106 is disposed on the amorphous substrate 102. The orientation control layer 106 has a crystalline structure. The crystalline structure of the orientation control layer 106 is preferably c-axis oriented. In other words, the orientation control layer 106 is preferably a c-axis orientation film. The crystal of the orientation control layer 106 preferably has rotational symmetry, for example, the crystal surface preferably has 6-fold symmetry. The crystal structure of the orientation control layer 106 preferably has a hexagonal close-packed structure, a face-centered cubic structure, or a structure equivalent thereto. A structure equivalent to a hexagonal close-packed structure or a face-centered cubic structure includes a crystal structure in which the c-axis is not 90 degrees with respect to the a-axis and the b-axis. The orientation control layer 106 having a hexagonal close-packed structure or an equivalent structure is preferably oriented (this orientation state is also referred to as the (0001) orientation of the hexagonal close-packed structure) in the (0001) direction, that is, in the c-axis direction, with respect to the first surface of the amorphous substrate 102 (the surface on which the first gallium nitride-based semiconductor layer 108 and the second gallium nitride-based semiconductor layer 110 are formed). The orientation control layer 106 having a face-centered cubic structure or an equivalent structure is preferably oriented in the (111) direction with respect to the first surface of the amorphous substrate 102 (this orientation state is also referred to as the (111) orientation of the face-centered cubic structure).

There is a lattice mismatch between the amorphous substrate 102 and the first gallium nitride-based semiconductor layer 108 and the second gallium nitride-based semiconductor layer 110. Therefore, in order to form the first gallium nitride-based semiconductor layer 108 and the second gallium nitride-based semiconductor layer 110 having crystallinity on the amorphous substrate 102, it is necessary to eliminate the lattice mismatch. By providing the orientation control layer 106 on the amorphous substrate 102, it is possible to manufacture the first gallium nitride-based semiconductor layer 108 and the second gallium nitride-based semiconductor layer 110 having high crystallinity by alleviating lattice mismatch. Since the orientation control layer 106 has a c-axis orientation crystal structure, the first gallium nitride-based semiconductor layer 108 and the second gallium nitride-based semiconductor layer 110 can be crystallized. That is, since the orientation control layer 106 has a c-axis orientation and a crystalline surface having 6-fold rotational symmetry such as a hexagonal close-packed structure or a face-centered cubic structure, the orientation of the first gallium nitride-based semiconductor layer 108 and the second gallium nitride-based semiconductor layer 110 can be controlled so that the c-axis of the first gallium nitride-based semiconductor layer 108 and the second gallium nitride-based semiconductor layer 110 grows in the film thickness direction (the direction perpendicular to the main surface of the amorphous substrate 102).

The orientation control layer 106 preferably has a high surface flatness. When the flatness of the orientation control layer 106 is expressed in terms of arithmetic mean roughness (Ra), Ra is preferably smaller than 2.5 nm, and more preferably smaller than 2.3 nm. Arithmetic mean roughness (Ra) is the value measured by atomic force microscopy (AFM). Since the orientation control layer 106 has a flat surface, the crystallinity of the first gallium nitride-based semiconductor layer 108 and the second gallium nitride-based semiconductor layer 110 can be enhanced.

A film thickness of the orientation control layer 106 is preferably from 5 nm to 500 nm, and more preferably from 10 nm to 200 nm. The film thickness can be measured by a contact type step meter, an optical film thickness meter (ellipsometry), and can be measured from images taken by a scanning electron microscope (SEM) or a transmission electron microscope (TEM). Since the orientation control layer 106 has a film thickness in this range, it is possible to have a flat surface with crystals oriented along the c-axis.

The orientation control layer 106 is formed of a metal or insulating material. The metal for forming the orientation control layer 106 is preferably titanium (Ti) or aluminum (AI). Other metal materials for forming the orientation control layer 106 may include magnesium (Mg), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), or alloys of these metals. As the material of the orientation control layer 106, a metal oxide material such as zinc oxide (ZnO), titanium dioxide (TiO₂), or a metal nitride material such as titanium nitride (TiN) may be used instead of a metal material. The material of the orientation control layer 106 may be graphene, magnesium diboride (MgB₂), BiLaTiO, SrFeO, BiFeO, BaFeO, ZnFeO, or PMnN-PZT. Further, a semiconductor material such as silicon (Si) or germanium (Ge), or a compound semiconductor material made of these semiconductor materials may be used as the conductive orientation control layer 106. Although silicon (Si) and germanium (Ge) are semiconductor materials, they have higher conductivity than the following insulating materials. The insulating material for forming the orientation control layer 106 is preferably c-axis-oriented aluminum nitride (AlN), aluminum oxide (Al₂O₃), silicon carbide (SiC), lithium niobate (LiNbO), BiLaTiO, SrFeO, SrFeO, BiFeO, BaFeO, ZnFeO, PMnN-PZT, or biological apatite (BAp). The orientation control layer 106 may be formed by sputtering using these metallic or insulating materials.

### 1-4. Gallium Nitride-Based Semiconductor Layer

The first gallium nitride-based semiconductor layer 108 and the second gallium nitride-based semiconductor layer 110 are formed of a semiconductor material containing gallium nitride. The first gallium nitride-based semiconductor layer 108 and the second gallium nitride-based semiconductor layer 110 are formed of, for example, a binary or ternary III-V compound semiconductor material such as gallium nitride (GaN), indium gallium nitride (InGaN), and aluminum gallium nitride (AlGaN). They may be formed of a compound semiconductor material such as indium nitride (InN), aluminum indium nitride (AlInN), indium gallium nitride (InGaN), or aluminum indium gallium nitride (AlInGaN). The first gallium nitride-based semiconductor layer 108 and the second gallium nitride-based semiconductor layer 110 formed of such a compound semiconductor material preferably have a stoichiometric composition but may deviate from the stoichiometric composition.

The first gallium nitride-based semiconductor layer 108 and the second gallium nitride-based semiconductor layer 110 are preferably crystalline. The first gallium nitride-based semiconductor layer 108 and the second gallium nitride-based semiconductor layer 110 are preferably single crystal, but may be polycrystalline, microcrystalline, or nanocrystalline. The crystal structures of the first gallium nitride-based semiconductor layer 108 and the second gallium nitride-based semiconductor layer 110 preferably have a wurtzite structure. The first gallium nitride-based semiconductor layer 108 and the second gallium nitride-based semiconductor layer 110 preferably have a c-axis orientation or a (111) orientation.

The first gallium nitride-based semiconductor layer 108 and the second gallium nitride-based semiconductor layer 110 have an n-type or p-type conductivity, and the electrical conductivity is controlled by the dopant concentration. As the n-type dopant, for example, one or more kinds of elements selected from silicon (Si) or germanium (Ge) are used. As the p-type dopant, for example, one or a plurality of elements selected from magnesium (Mg), zinc (Zn), cadmium (Cd), and beryllium (Be) are used.

The first gallium nitride-based semiconductor layer 108 and the second gallium nitride-based semiconductor layer 110 are disposed in contact with the orientation control layer 106. Since the orientation control layer 106 has a crystal structure of c-axis orientation, the crystallinity of the first gallium nitride-based semiconductor layer 108 and the second gallium nitride-based semiconductor layer 110 can be c-axis orientation or (111) orientation. The first gallium nitride-based semiconductor layer 108 and the second gallium nitride-based semiconductor layer 110 may include an amorphous structure near the interface with the orientation control layer 106 but preferably have crystallinity in a region (bulk) away from the interface. Since at least the first gallium nitride-based semiconductor layer 108 has crystallinity, a Schottky junction with few interface defects can be formed with the first electrode 114, and a Schottky barrier diode can be formed as the rectifying device 100A.

When the first gallium nitride-based semiconductor layer 108 and the second gallium nitride-based semiconductor layer 110 are gallium nitride layers and the gallium nitride layers are formed by sputtering, the substrate temperature (set temperature) at the time of sputtering is controlled to 100° C. to 600° C. Since the orientation control layer 106 is disposed on the substrate of the gallium nitride layers, the gallium nitride layers can be crystallized even if the substrate temperature is 600° C. or lower.

The sputtering target mounted on the sputtering apparatus is suitably selected in accordance with the compositions of the first gallium nitride-based semiconductor layer 108 and the second gallium nitride-based semiconductor layer 110 to be fabricated. The sputtering target is a sintered gallium nitride-based semiconductor material. Since the dopant concentrations of the first gallium nitride-based semiconductor layer 108 and the second gallium nitride-based semiconductor layer 110 are different, it is preferable to fabricate each layer using a different sputtering target.

Argon (Ar) or a mixed gas of argon (Ar) and nitrogen (N₂) are used as the gas (sputter gas) used for the deposition of the sputtering film. A bipolar sputtering apparatus, a magnetron sputtering apparatus, a dual magnetron sputtering apparatus, a counter target sputtering apparatus, an ion-beam sputtering apparatus, an inductively coupled plasma (ICP) sputtering apparatus, and the like can be used as the sputtering apparatus.

The thickness of the first gallium nitride-based semiconductor layer 108 and the second gallium nitride-based semiconductor layer 110 is not limited. The first gallium nitride-based semiconductor layer 108 may be formed in a Schottky junction with the first electrode 114 and may have a film thickness of 50 nm to 3000 nm, for example, 200 nm to 1000 nm. The second gallium nitride-based semiconductor layer 110 may only form an ohmic junction with the second electrode 116 and may have a film thickness of 50 nm to 3000 nm, for example, 200 nm to 1000 nm.

### 1-5. First Electrode and Second Electrode

The first electrode 114 is disposed on the first gallium nitride-based semiconductor layer 108, and the second electrode 116 is disposed on the second gallium nitride-based semiconductor layer 110. The first electrode 114 is disposed to form a Schottky junction with the first gallium nitride-based semiconductor layer 108, and the second electrode 116 is disposed to be in ohmic contact with the second gallium nitride-based semiconductor layer 110.

When the first gallium nitride-based semiconductor layer 108 is n-type and has a work function of 3 eV to 4 eV, a material having a conductivity of 4.5 eV or more such as nickel (Ni), gold (Au), platinum (Pt), silver (Ag), and p-type silicon is selected as the first electrode 114. The first electrode 114 may be formed of a metal having such a work function when the metal in contact with the first gallium nitride-based semiconductor layer 108 is formed of such a metal, and other metal layers such as aluminum (Al) may be laminated on top of this metal layer. As the second electrode 116, a metal having a work function smaller than 4.5 eV, such as aluminum (Al) and titanium (Ti), is selected. The second electrode 116 may be made of a conductive metallic material such as indium oxide, zinc oxide, indium tin oxide, or the like. The second electrode 116 may be made of the same metal as the first electrode 114. Since the second gallium nitride-based semiconductor layer 110 in contact with the second electrode 116 includes a high concentration of n-type impurities (n-type dopants) and is sufficiently reduced in resistance, a contact similar to an ohmic contact can be formed.

### 2. Operation of Rectifying Device

As shown in FIG. 1B, the rectifying device 100A includes a structure in which the first gallium nitride-based semiconductor layer 108 and the second gallium nitride-based semiconductor layer 110 are in contact with the orientation control layer 106. The orientation control layer 106 has conductivity in the present embodiment. Therefore, when the rectifying device 100A is biased in the forward direction, a current flows from the first electrode 114 to the second electrode 116 through the first gallium nitride-based semiconductor layer 108, the orientation control layer 106, and the second gallium nitride-based semiconductor layer 110. Since the side surface of the second gallium nitride-based semiconductor layer 110 and the first gallium nitride-based semiconductor layer 108 have a region for forming a junction, a current flowing through the junction may also exist. However, since the orientation control layer 106 is conductive, it is considered that when the rectifying device 100A is biased in the forward direction, the current flowing from the first electrode 114 to the second electrode 116 via the orientation control layer 106 becomes dominant.

The first gallium nitride-based semiconductor layer 108 and the second gallium nitride-based semiconductor layer 110 are formed on the orientation control layer 106 to have crystallinity. Thus, by arranging the first gallium nitride-based semiconductor layer 108 and the second gallium nitride-based semiconductor layer 110 in parallel with each other, it is possible to improve the crystallinity of these two layers because the crystal of these two layers is directly controlled by the orientation control layer 106. It is possible to prevent the generation of crystalline defects continuous with the two-gallium nitride-based semiconductor layers.

The rectifying device may include a structure in which the first gallium nitride-based semiconductor layer 108 and the second gallium nitride-based semiconductor layer 110 are laminated in the vertical direction. However, since the first gallium nitride-based semiconductor layer 108 and the second gallium nitride-based semiconductor layer 110 are formed by sputtering, when the semiconductor layer includes a stacked structure, crystalline defects that extend over the two layers may be generated. When such a crystalline defect is formed, the reverse breakdown voltage is lowered, and their concern that a leakage current may be generated through the crystalline defect. On the other hand, the rectifying device 100A of the present embodiment includes a structure in which the first gallium nitride-based semiconductor layer 108 and the second gallium nitride-based semiconductor layer 110 are arranged in parallel on the amorphous substrate 102, so that the breakdown voltage is excellent and the leakage current (reverse current) can be reduced.

### 3. Method for Manufacturing

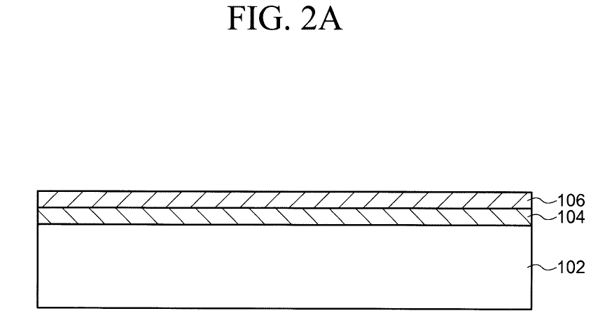

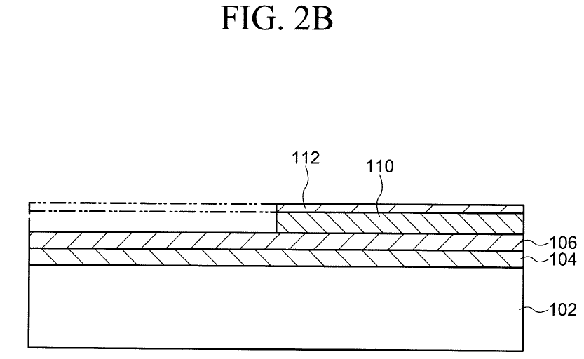

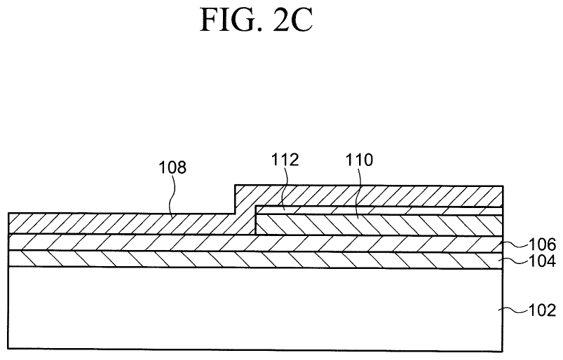

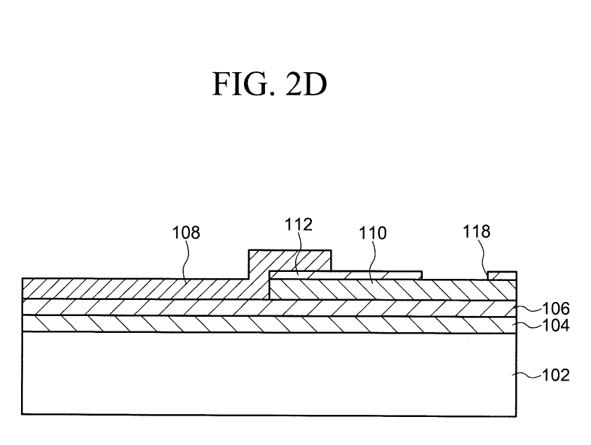

FIG. 2A to FIG. 2D show a method for manufacturing the rectifying device 100A according to the present embodiment. As shown in FIG. 2A, the base insulating layer 104 and the orientation control layer 106 are formed on the amorphous substrate 102. The underlying insulating layer 104 is formed by, for example, plasma CVD (Chemical Vapor Deposition). The underlying insulating layer 104 has an arbitrary configuration, but is formed to include, for example, a laminated structure of a silicon nitride film and a silicon oxide film. The orientation control layer 106 is formed by sputtering. The orientation control layer 106 is formed, for example, by sputtering of titanium (Ti). The film thickness of the underlying insulating layer 104 is as described in Section 1-2, and the film thickness of the orientation control layer 106 is as described in Section 1-3.

FIG. 2B shows a step in which the second gallium nitride-based semiconductor layer 110 is formed on the orientation control layer 106, an insulating layer 112 is formed, and some of these layers are removed by etching. The second gallium nitride-based semiconductor layer 110 is formed on the orientation control layer 106, and the orientation control layer 106 is exposed in the etched region. The second gallium nitride-based semiconductor layer 110 is formed by sputtering. The second gallium nitride-based semiconductor layer 110 has n-type conductivity, uses silicon (Si) as a dopant, for example, and is formed so that the carrier concentration (or dopant concentration) is 5×10¹⁸ to 5×10²¹/cm³. The insulating layer 112 is a silicon oxide film or a silicon nitride film and is formed by sputtering or plasma CVD. The thickness of the insulating layer 112 is not limited and is formed to be 50 nm to 5000 nm, for example.

FIG. 2C shows a step of forming the first gallium nitride-based semiconductor layer 108. The first gallium nitride-based semiconductor layer 108 is formed by sputtering. The first gallium nitride-based semiconductor layer 108 is formed by depositing the orientation control layer 106 in an exposed region from the second gallium nitride-based semiconductor layer 110. Furthermore, the second gallium nitride-based semiconductor layer 110 and the insulating layer 112 are formed to cover an upper face of the insulating layer 112 over a step portion formed by laminating the insulating layer 112. The first gallium nitride-based semiconductor layer 108 has n-type conductivity, for example, silicon (Si) is used as a dopant, and is formed so that the carrier concentration (or dopant concentration) is 5×10¹⁵ to 1×10¹⁷/cm³. The first gallium nitride-based semiconductor layer 108 is preferably formed in contact with the side surface of the second gallium nitride-based semiconductor layer 110 at the stepped portion.

FIG. 2D shows etching of the first gallium nitride-based semiconductor layer 108 to expose the upper surface of the insulating layer 112. Furthermore, an opening 118 for exposing the second gallium nitride-based semiconductor layer 110 is formed in the insulating layer 112. The first gallium nitride-based semiconductor layer 108 and the second gallium nitride-based semiconductor layer 110 are made of a gallium nitride-based semiconductor having the same composition. Since the insulating layer 112 is disposed on the second gallium nitride-based semiconductor layer 110, the first gallium nitride-based semiconductor layer 108 can be selectively etched to form the structure shown in FIG. 2D.

Thereafter, the first electrode 114 is formed on the first gallium nitride-based semiconductor layer 108 and the second electrode 116 is formed on the second gallium nitride-based semiconductor layer 110, whereby the rectifying device 100A having the structure shown in FIG. 1B can be fabricated.

Although the above process has been described on the assumption that the first gallium nitride-based semiconductor layer 108 and the second gallium nitride-based semiconductor layer 110 have the same composition, the two semiconductor layers may have different compositions. For example, the first gallium nitride-based semiconductor layer 108 may be made of aluminum gallium nitride (AlGaN) and the second gallium nitride-based semiconductor layer 110 may be made of gallium nitride (GaN).

As described above, in the rectifying device 100A according to the present embodiment, since the first gallium nitride-based semiconductor layer 108 and the second gallium nitride-based semiconductor layer 110 are disposed side by side on the orientation control layer 106, even if these semiconductor layers are prepared by a thin film process of sputtering, they have a high breakdown voltage and a leakage current can be reduced at the time of reverse bias. According to the present embodiment, the rectifying device 100A having the structure shown in FIG. 1A and FIG. 1B can be formed on the amorphous substrate 102 at a temperature of 600° C. or less. Since the area of the amorphous substrate 102 can be enlarged and a large number of rectifying devices 100D can be individually divided from one substrate, productivity can be improved.

### Second Embodiment

According to the rectifying device 100A of the first embodiment, the orientation control layer 106 may be formed of an insulating material. That is, the orientation control layer 106 in the rectifying device 100A shown in FIG. 1A and FIG. 1B may have insulating properties. In this case, the orientation control layer 106 is formed of aluminum nitride (AlN) or aluminum oxide (Al₂O₃) in a c-axis orientation as described in the first embodiment.

When a forward bias is applied to the rectifying device 100A including the orientation control layer 106 having an insulating property, a current flows from the first electrode 114 to the second electrode 116 via the first gallium nitride-based semiconductor layer 108, via the junction between the first gallium nitride-based semiconductor layer 108 and the second gallium nitride-based semiconductor layer 110, and the second gallium nitride-based semiconductor layer 110. The rectifying device 100A is a Schottky barrier diode which exhibits rectifying characteristics by a Schottky barrier formed between the first electrode 114 and the first gallium nitride-based semiconductor layer 108, but the junction between the n-type semiconductor layers formed at the junction between the first gallium nitride-based semiconductor layer 108 and the second gallium nitride-based semiconductor layer 110 is substantially an n⁻/n⁺ junction and is biased in the forward direction during the forward bias of the rectifying device 100A, so that the current voltage characteristic is hardly affected.

When the orientation control layer 106 has an insulating property, since the forward current flows through the first gallium nitride-based semiconductor layer 108 and the second gallium nitride-based semiconductor layer 110 in the lateral direction (in a direction parallel to the surface of the amorphous substrate 102), the length of the drift layer formed in the first gallium nitride-based semiconductor layer 108 can be set according to the distance from the first electrode 114 to the junction, so that it is not necessary to form the first gallium nitride-based semiconductor layer 108 thick, and the degree of freedom in device design can be increased.

The rectifying device 100A described in this embodiment is the same as the rectifying device shown in the first embodiment except that the orientation control layer 106 has an insulating property, and the same advantageous effect as the first embodiment can be obtained in addition to the advantages described above.

### Third Embodiment

The present embodiment shows a configuration of the orientation control layer 106 different from that of the first embodiment and the second embodiment. The following description will focus on a configuration different from that of the first embodiment and will exclude overlapping descriptions.

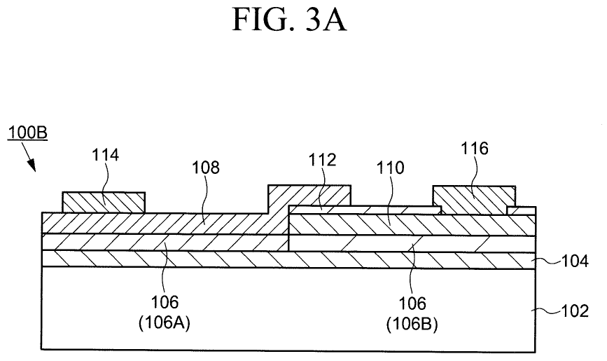

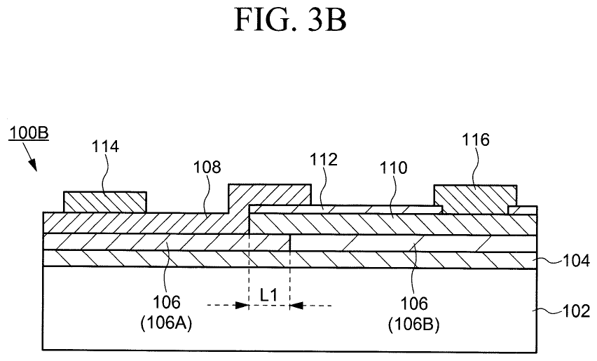

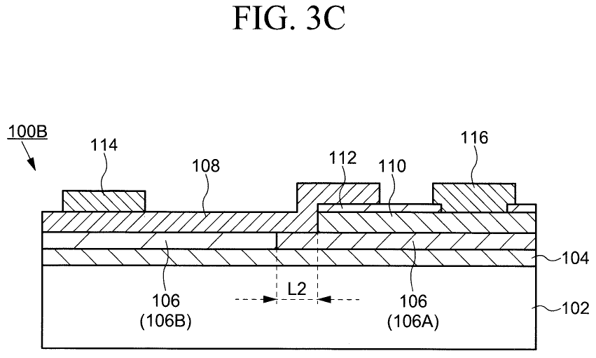

FIG. 3A is a cross-sectional view of a rectifying device 100B according to the present embodiment. As shown in FIG. 3A, the orientation control layer 106 includes a structure in which the first orientation control layer 106A and the second orientation control layer 106B are arranged side by side on the amorphous substrate 102. The first orientation control layer 106A is insulating, and the second orientation control layer 106B is conductive. That is, the first orientation control layer 106A is formed of an insulating material selected from c-axis-oriented aluminum nitride (AlN) and aluminum oxide (Al₂O₃), and the second orientation control layer 106B is formed of a metal material selected from titanium (Ti) and aluminum (Al).

The first gallium nitride-based semiconductor layer 108 is disposed on the first orientation control layer 106A, and the second gallium nitride-based semiconductor layer 110 is disposed on the second orientation control layer 106B. As shown in FIG. 3A, the rectifying device 100B includes a structure in which the first gallium nitride-based semiconductor layer 108 is in contact with a side surface (a side surface exposed from the insulating layer 112) of the second gallium nitride-based semiconductor layer 110, and a semiconductor junction is formed at this contact portion. It is preferable that the semiconductor junction portion overlaps the boundary portion between the first orientation control layer 106A and the second orientation control layer 106B.

The rectifying device 100B according to the present embodiment includes such a structure, similar to the second embodiment, when the rectifying device 100B is biased in the forward direction, a current path through which a current flows from the first electrode 114 to the second electrode 116 can be formed via the first gallium nitride-based semiconductor layer 108, the junction between the first gallium nitride-based semiconductor layer 108 and the second gallium nitride-based semiconductor layer 110, the second gallium nitride-based semiconductor layer 110, and the second orientation control layer 106B. Since the second orientation control layer 106B is formed of a metal material having a lower resistance than that of the second gallium nitride-based semiconductor layer 110, the influence of the resistance loss (series resistance component) caused by the second gallium nitride-based semiconductor layer 110 can be reduced, and the forward characteristic can be improved.

As shown in FIG. 3B, a portion where the first gallium nitride-based semiconductor layer 108 and the second gallium nitride-based semiconductor layer 110 are semiconductor joined may be located on the first orientation control layer 106A. In other words, the second gallium nitride-based semiconductor layer 110 may be disposed to extend over the first orientation control layer 106A. Since the second gallium nitride-based semiconductor layer 110 includes a structure stretched on the insulating first orientation control layer 106A, it is possible for the extended portion L1 to allow a current to flow only in the second gallium nitride-based semiconductor layer 110 without flowing to the first orientation control layer 106A, and this portion can be used as a drift layer of the rectifying device 100B. Since the length of the second gallium nitride-based semiconductor layer 110 extending over the first orientation control layer 106A can be freely set, it is possible to provide a degree of freedom in device design.

As shown in FIG. 3C, the first gallium nitride-based semiconductor layer 108 may be disposed on the second orientation control layer 106B having conductivity, the second gallium nitride-based semiconductor layer 110 may be disposed on the first orientation control layer 106A having an insulating property, and the first gallium nitride-based semiconductor layer 108 may extend over the first orientation control layer 106A. Since the first gallium nitride-based semiconductor layer 108 is disposed on the second orientation control layer 106B having conductive properties, resistance loss during forward bias can be reduced. Since the semiconductor junction of the first gallium nitride-based semiconductor layer 108 and the second gallium nitride-based semiconductor layer 110 is disposed on the first orientation control layer 106A having an insulating property, the portion L2 to which the first gallium nitride-based semiconductor layer 108 extends can be used as a drift layer, and breakdown voltage can be enhanced.

The rectifying device 100B according to the present embodiment is a Schottky barrier diode, and is similar to the rectifying device 100A according to the second embodiment except that the orientation control layer 106 includes a first orientation control layer 106A having an insulating property and a second orientation control layer 106B having a conductive property, and in addition to the advantages described above, the same operation and effect as the rectifying device 100A according to the second embodiment can be obtained.

### Fourth Embodiment

The present embodiment shows a rectifying device having a structure different from that of the third embodiment in the case where the orientation control layer 106 includes a first orientation control layer 106A having an insulating property and a second orientation control layer 106B having a conductive property, as shown in the third embodiment. The following description will focus on a configuration different from that of the third embodiment and will exclude overlapping descriptions.

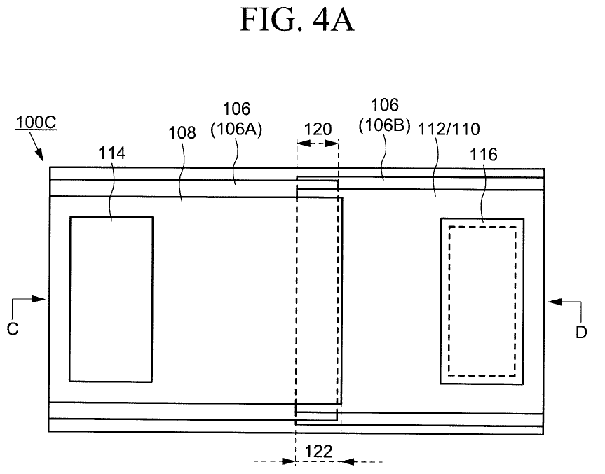

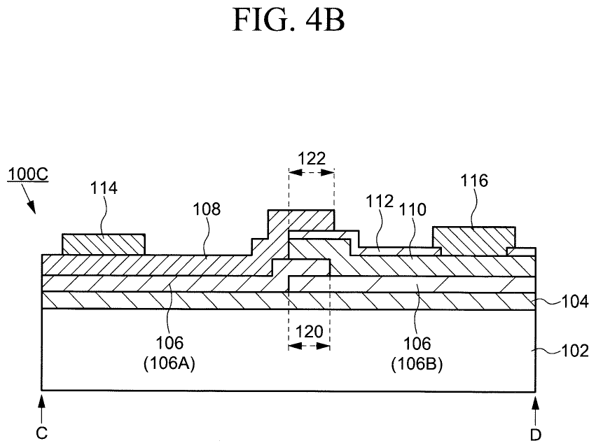

FIG. 4A and FIG. 4B show the structure of the rectifying device 100C according to the present embodiment. FIG. 4A shows a plan view of the rectifying device 100C. FIG. 4B shows a cross-sectional view corresponding to the section C-D shown in FIG. 4A.

As shown in FIG. 4A, the rectifying device 100C according to the present embodiment includes a first overlapping portion 120 in which the first orientation control layer 106A having insulation and the second orientation control layer 106B having conductivity overlap in a plan view. As shown in FIG. 4B, the first overlapping portion 120 includes a laminated structure such that the end of the first orientation control layer 106A overlaps the second orientation control layer 106B.

As shown in FIG. 4A, the rectifying device 100C according to the present embodiment includes a second overlapping portion 122 in which the first gallium nitride-based semiconductor layer 108 and the second gallium nitride-based semiconductor layer 110 (and the insulating layer 112) overlap in a plan view. As shown in FIG. 4B, the second overlapping portion 122 includes a structure in which the ends of the first gallium nitride-based semiconductor layer 108 overlap the second gallium nitride-based semiconductor layer 110 (and the insulating layer 112).

As shown in FIG. 4B, the first gallium nitride-based semiconductor layer 108 is in contact with a side surface (a side surface exposed from the insulating layer 112) of the second gallium nitride-based semiconductor layer 110 on the first overlapping portion 120, and a semiconductor junction is formed at this contact portion. Since the second gallium nitride-based semiconductor layer 110 is disposed in the first overlapping portion 120 to extend over the first orientation control layer 106A having an insulating property, this region can be used as the drift layer as in the third embodiment.

As described above, the Schottky barrier diode as the rectifying device 100C can be obtained by the structure shown in FIG. 4A and FIG. 4B as in the third embodiment. The rectifying device 100C according to the present embodiment is the same as the rectifying device 100B according to the third embodiment except that the rectifying device 100C includes the first overlapping portion 120 and the second overlapping portion 122, and the same operation and effect as the rectifying device 100B according to the third embodiment can be obtained.

### Fifth Embodiment

The present embodiment shows an example of a rectifying device having a structure different from that of the first to fourth embodiments. The following description will focus on the parts that differ from those of the first to fourth embodiments, and will exclude overlapping descriptions.

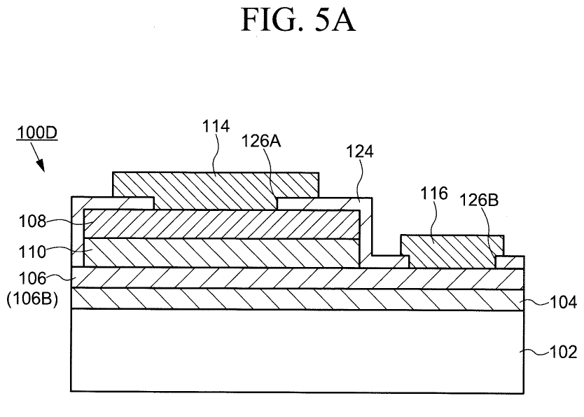

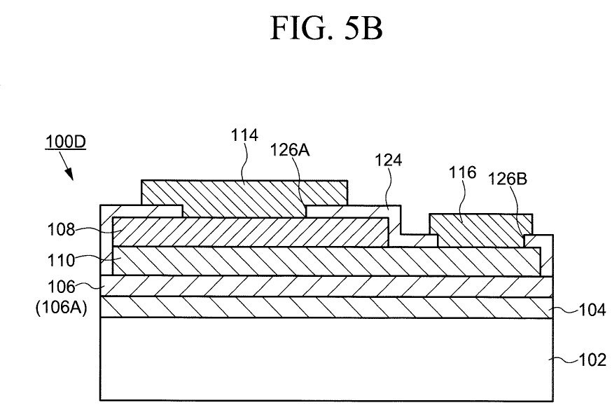

FIG. 5A is a cross-sectional view of the rectifying device 100D according to the present embodiment. As shown in FIG. 5A, the rectifying device 100D includes a structure in which the orientation control layer 106, the second gallium nitride-based semiconductor layer 110, the first gallium nitride-based semiconductor layer 108, and the first electrode 114 are laminated on the amorphous substrate 102. As shown in FIG. 5A, the second orientation control layer 106B having the same conductivity as that described in the third embodiment is used as the orientation control layer. The underlying insulating layer 104 may be disposed between the amorphous substrate 102 and the orientation control layer 106.

The first gallium nitride-based semiconductor layer 108 and the second gallium nitride-based semiconductor layer 110 are formed by sputtering. The second gallium nitride-based semiconductor layer 110 has crystallinity by being formed on the second orientation control layer 106B. Therefore, the first gallium nitride-based semiconductor layer 108 formed on the second gallium nitride-based semiconductor layer 110 is also crystalline.

The first electrode 114 is disposed on the first gallium nitride-based semiconductor layer 108 to form a Schottky barrier. The second orientation control layer 106B is disposed in contact with the lower surface of the second gallium nitride-based semiconductor layer 110 and extends outward from a region where the first gallium nitride-based semiconductor layer 108 and the second gallium nitride-based semiconductor layer 110 are laminated. The second electrode 116 is disposed in a region where the second orientation control layer 106B having a conductive property extends. By having such a structure, it is possible to form a structure in which a Schottky barrier is interposed between the first electrode 114 and the second electrode 116. As described in the second embodiment, the junction between the n-type semiconductor layers (n−/n+ junction) in the region where the first gallium nitride-based semiconductor layer 108 and the second gallium nitride-based semiconductor layer 110 come into contact with each other is biased in the forward direction when the rectifying device 100D is biased in the forward direction, so that the current-voltage characteristic is not affected.

A passivation layer 124 is disposed to cover the upper and side surfaces of the first gallium nitride-based semiconductor layer 108 and the side surfaces of the second gallium nitride-based semiconductor layer 110. The passivation layer 124 may be extended to cover the upper surface of the second orientation control layer 106B. The passivation layer 124 is formed of, for example, a silicon nitride film or a silicon oxide film. It is possible to prevent surface recombination by providing the passivation layer 124. The first electrode 114 is disposed in a first opening 126A formed in the passivation layer 124 so as to be in contact with the first gallium nitride-based semiconductor layer 108. The second electrode 116 is disposed in contact with the second orientation control layer 106B at a second opening 126B formed in the passivation layer 124.

FIG. 5B shows a structure of the rectifying device 100D in which the first gallium nitride-based semiconductor layer 108 and the second gallium nitride-based semiconductor layer 110 are laminated in the vertical direction, in which the first orientation control layer 106A having the same insulating properties as those described in the third embodiment is used as the orientation control layer 106. The second gallium nitride-based semiconductor layer 110 and the first gallium nitride-based semiconductor layer 108 are laminated on the first orientation control layer 106A in this order.

The second gallium nitride-based semiconductor layer 110 is disposed to extend further outward from a region laminated with the first gallium nitride-based semiconductor layer 108. The second electrode 116 is disposed to form ohmic contact with the second gallium nitride-based semiconductor layer 110 in the extended region. As shown in FIG. 5B, even if the orientation control layer 106 has insulating properties, the rectifying device 100D can be obtained by arranging the second electrode 116 in ohmic contact with the second gallium nitride-based semiconductor layer 110.

The rectifying device 100D shown in FIG. 5A and FIG. 5B is a Schottky barrier diode, and can be fabricated on the amorphous substrate 102 at a temperature of 600° C. or lower by sputtering the second gallium nitride-based semiconductor layer 110 and the first gallium nitride-based semiconductor layer 108 on the orientation control layer 106 (the second orientation control layer 106B). Since the area of the amorphous substrate 102 can be enlarged and a large number of rectifying devices 100D can be divided into individual pieces from one substrate, productivity can be improved.

What is claimed is:

1. A rectifying device comprising:
an amorphous substrate;
an orientation control layer on the amorphous substrate;
a first gallium nitride-based semiconductor layer and a second gallium nitride-based semiconductor layer on the orientation control layer;
a first electrode forming a Schottky junction with the first gallium nitride-based semiconductor layer; and
a second electrode forming an ohmic junction with the second gallium nitride-based semiconductor layer.

2. The rectifying device according to claim 1, wherein the first gallium nitride-based semiconductor layer and the second gallium nitride-based semiconductor layer are in contact with the orientation control layer.

3. The rectifying device according to claim 2, wherein the first gallium nitride-based semiconductor layer and the second gallium nitride-based semiconductor layer are arranged side by side on the orientation control layer.

4. The rectifying device according to claim 3, wherein the first gallium nitride-based semiconductor layer and the second gallium nitride-based semiconductor layer overlap in a plan view.

5. The rectifying device according to claim 3, wherein the first gallium nitride-based semiconductor layer and the second gallium nitride-based semiconductor layer include a junction portion in contact with each other,
wherein the junction portion extends across a top surface of the orientation control layer.

6. The rectifying device according to claim 1, wherein the orientation control layer has a conductive or an insulating property.

7. The rectifying device according to claim 1, wherein the orientation control layer includes a first orientation control layer having an insulating property and a second orientation control layer having a conductive property;
the first orientation control layer and the second orientation control layer are arranged side by side on the amorphous substrate; and
the first gallium nitride-based semiconductor layer is arranged on the first orientation control layer, and the second gallium nitride-based semiconductor layer is arranged on the second orientation control layer.

8. The rectifying device according to claim 7, wherein the first orientation control layer and the second orientation control layer include a first overlapping portion overlapping each other in a plan view; and
the first gallium nitride-based semiconductor layer and the second gallium nitride-based semiconductor layer include a second overlapping portion overlapping each other in a plan view,
wherein the first overlapping portion and the second overlapping portion are overlap in a plan view.

9. The rectifying device according to claim 1, wherein a conductive type of the first gallium nitride-based semiconductor layer and a conductive type of the second gallium nitride-based semiconductor layer are the same,
wherein a dopant concentration of the first gallium nitride-based semiconductor layer is lower than a dopant concentration of the second gallium nitride-based semiconductor layer.

10. The rectifying device according to claim 9, wherein the first gallium nitride-based semiconductor layer and the second gallium nitride-based semiconductor layer are crystalline,
wherein the crystalline has a c-axis orientation.

11. The rectifying device according to claim 1, wherein the orientation control layer is a metal or a metal oxide having conductivity.

12. The rectifying device according to claim 11, wherein the metal is one selected from titanium (Ti), aluminum (Al), silver (Ag), nickel (Ni), copper (Cu), strontium (Sr), rhodium (Rh), palladium (Pd), iridium (Ir), platinum (Pt), and gold (Au); the metal oxide is an oxide of zinc (Zn) or titanium (Ti).

13. The rectifying device according to claim 1, wherein the orientation control layer is aluminum nitride (AlN) or aluminum oxide (Al₂O₃).

14. The rectifying device according to claim 1, wherein the orientation control layer, the second gallium nitride-based semiconductor layer, and the first gallium nitride-based semiconductor layer are laminated on the amorphous substrate in this order.
